(19) United States
(12) Patent Application Publication
(10) Pub. No.: US 2010/0226104 A1
(43) Pub. Date: Sep. 9, 2010

(54) ELECTRICAL EQUIPMENT ASSEMBLY AND OUTDOOR UNIT OF AIR CONDITIONER DISPOSED WITH THE ELECTRICAL EQUIPMENT ASSEMBLY

(75) Inventors: Hisashi Takeichi, Osaka (JP); Naohiro Kawasaki, Osaka (JP)

Correspondence Address: GLOBAL IP COUNSELORS, LLP, 1233 20TH STREET, NW, SUITE 700, WASHINGTON, DC, 20036-2680, US

(73) Assignee: DAIKIN INDUSTRIES, LTD., Osaka-shi, Osaka (JP)

(21) Appl. No.: 12/161,845

(22) PCT Filed: Jan. 30, 2007
(86) PCT No.: PCT/JP2007/051501

§ 371 Date: Jul. 23, 2008

(30) Foreign Application Priority Data
Feb. 1, 2006 (JP) 2006-024402

(51) Int. Cl. H05K 7/00

(52) U.S. Cl. 361/752

(57) ABSTRACT

An electrical equipment assembly includes a control board and a frame. The control board is disposed lengthwise inside a casing, and various types of electrical parts are mounted on the control board. The frame is a member that holds the control board. Slits that drain water that is present between the frame and the control board are formed in a lower portion of the frame. Water guide paths that guide the water to the slits are formed in a surface of the frame that faces a board surface of the control board.

### TECHNICAL FIELD

The present invention relates to an electrical equipment assembly and to an outdoor unit of an air conditioner disposed with the electrical equipment assembly, and particularly to an electrical equipment assembly that is disposed inside a casing of an outdoor unit and to an outdoor unit of an air conditioner disposed with the electrical equipment assembly.

### BACKGROUND ART

As an outdoor unit of a conventional air conditioner, there is an outdoor unit that has a structure where the inside of a substantially rectangular parallelepiped box-shaped casing is divided into a blower chamber and a machine chamber by a partition plate that extends in a vertical direction. In the blower chamber are mainly disposed an outdoor heat exchanger and an outdoor fan. Further, in the machine chamber are mainly disposed a compressor, refrigerant circuit components configured by valves and refrigerant pipes, and an electrical equipment assembly. As the electrical equipment assembly, there is an electrical equipment assembly disposed with a control board that is disposed lengthwise and a frame that holds the control board. The frame includes a vertical plate portion that faces a board surface of the control board and a peripheral edge plate portion that extends sideways from the vertical plate portion so as to surround the peripheral edge portion of the control board (see Patent Document 1).

<Patent Document 1>
JP-A No. 9-236284

### DISCLOSURE OF THE INVENTION

On the vertical plate portion of the frame of the aforementioned conventional electrical equipment assembly, an inverter control element is attached to the surface on the side where the control board is disposed, and a heat sink for cooling the inverter control element is attached to the surface on the opposite side of the side where the control board is disposed. Additionally, when the heat sink is attached, the heat sink projects into the inside of the blower chamber through an opening in the partition plate, so there is the potential for water to enter the control board side of the frame from the portion of the vertical plate portion of the frame to which the heat sink is attached, that is, between the control board and the frame. Additionally, when water enters between the control board and the frame, there is the potential for problems to occur, such as the water ending up accumulating due to surface tension between the control board and the frame (particularly the lower portion of the frame), the water contacting the pattern portion of the control board, and the control board short-circuiting. To counter this, there are also instances where water is prevented from entering between the control board and the frame by disposing a seal member or the like on the portion where the heat sink is attached to the frame, but in this case, the seal member costs money, attachment of the seal member takes effort, and there is the potential for ingression of water resulting from ununiformity in the attachment of the seal member to occur.

It is an object of the present invention to make it difficult, in an electrical equipment assembly that is disposed inside a casing of an outdoor unit, for problems to occur even when water enters between a control board and a frame, such as the water contacting the pattern on the control board and the control board short-circuiting.

An electrical equipment assembly pertaining to a first invention is an electrical equipment assembly which, in an outdoor unit of an air conditioner that has a structure where the inside of a casing is divided into a blower chamber and a machine chamber by a partition plate that extends vertically, is disposed in the machine chamber, the electrical equipment assembly comprising a control board and a frame. The control board is disposed lengthwise inside the casing, and various types of electrical parts are mounted on the control board. The frame is a member that holds the control board. Water drainage portions that drain water that is present between the frame and the control board are formed in a lower portion of the frame. Water guide paths that guide the water to the water drainage portions are formed in a surface of the frame that faces a board surface of the control board.

In this electrical equipment assembly, the frame holds the control board that is disposed lengthwise, the water drainage portions that drain water that is present between the frame and the control board are formed in the lower portion of the frame, and the water guide paths that guide the water to the water drainage portions are formed in the surface of the frame that faces the board surface of the control board, so water that is present between the control board and the frame can be speedily drained and prevented from accumulating. Thus, in this electrical equipment assembly, it can be made difficult for problems to occur even when water enters between the control board and the frame, such as the water contacting the pattern on the control board and the control board short-circuiting, and the reliability of the electrical equipment assembly can be improved.

An electrical equipment assembly pertaining to a second invention comprises the electrical equipment assembly pertaining to the first invention, wherein the water guide paths are disposed on an upper side of the water drainage portions.

In this electrical equipment assembly, the water guide paths are disposed on the upper side of the water drainage portions, so water entering between the control board and the frame can be guided by the force of gravity to the water drainage portions.

An electrical equipment assembly pertaining to a third invention comprises the electrical equipment assembly pertaining to the second invention, wherein the frame includes a lengthwise plate portion that faces the board surface of the control board and a sideways plate portion that extends sideways from a surface of the lengthwise plate portion on the control board side such that the sideways plate portion is positioned on a lower side of the control board.

In this electrical equipment assembly, when water enters between the control board and the frame, it becomes easy for the water to accumulate in the interconnecting portion of the lengthwise plate portion and the sideways plate portion and in the vicinity of that interconnecting portion, but because the water guide paths are formed in the lengthwise plate portion that configures the surface that faces the board surface of the control board, the water that is present between the control board and the frame can be guided to the water drainage portions, speedily drained, and prevented from accumulating in the interconnecting portion of the lengthwise plate portion and the sideways plate portion and in the vicinity of that interconnecting portion.

An electrical equipment assembly pertaining to a fourth invention comprises the electrical equipment assembly pertaining to the third invention, wherein a vertical direction clearance between the sideways plate portion and the control board is equal to or less than 3 mm.

In this electrical equipment assembly, when water enters between the control board and the frame, it becomes easy for the water to accumulate in the portion between the sideways plate portion and the control board and in the vicinity of that portion because the sideways plate portion and the control board are disposed in extremely close proximity to each other, but because the water guide paths and the water drainage portions are formed, the water that is present between the control board and the frame can be guided to the water drainage portions by the water guide paths, speedily drained, and prevented from accumulating in the portion between the sideways plate portion and the control board and in the vicinity of that portion.

An electrical equipment assembly pertaining to a fifth invention comprises the electrical equipment assembly pertaining to the third or fourth invention, wherein the water drainage portions are formed in an interconnecting portion of the lengthwise plate portion and the sideways plate portion and/or in the vicinity of that interconnecting portion.

In this electrical equipment assembly, when water enters between the control board and the frame, the water can be reliably prevented from accumulating in the interconnecting portion of the lengthwise plate portion and the sideways plate portion and in the vicinity of that interconnecting portion because the water drainage portions are formed in the interconnecting portion of the lengthwise plate portion and the sideways plate portion and/or in the vicinity of that interconnecting portion where it is easy for water to accumulate.

An electrical equipment assembly pertaining to a sixth invention comprises the electrical equipment assembly pertaining to the third or fourth invention, wherein the water drainage portions are formed in the sideways plate portion.

In this electrical equipment assembly, when water enters between the control board and the frame, the water can be reliably prevented from accumulating in the interconnecting portion of the lengthwise plate portion and the sideways plate portion and in the vicinity of that interconnecting portion because the water drainage portions are formed in the sideways plate portion that is positioned on the lowermost side of the portion between the control board and the frame. Further, when the sideways plate portion and the control board are disposed in extremely close proximity to each other, the water can be reliably prevented from accumulating in the portion between the sideways plate portion and the control board and in the vicinity of that portion.

An electrical equipment assembly pertaining to a seventh invention comprises the electrical equipment assembly pertaining to any of the third to sixth inventions, projecting portions that project toward the control board from the surface of the lengthwise plate portion on the control board side and extend downward toward the drainage portions are formed on the lengthwise plate portion. The water guide paths are configured by the projecting portions.

In this electrical equipment assembly, the water guide paths are configured by the projecting portions, which can also contribute to improving the strength of the lengthwise plate portion of the frame.

An electrical equipment assembly pertaining to an eighth invention comprises the electrical equipment assembly pertaining to any of the third to seventh inventions, wherein an inverter control element is attached to the surface of the lengthwise plate portion on the control board side and a heat sink is attached to a surface of the lengthwise plate portion on the opposite side of the control board side for cooling during operation of the inverter control element. The water guide paths are formed on a lower side of the portion to which the heat sink is attached.

In this electrical equipment assembly, the inverter control element is attached to the surface of the lengthwise plate portion on the control board side and a heat sink is attached to the surface of the lengthwise plate portion on the opposite side of the control board side for cooling during operation of the inverter control element, so there is the potential for water to enter from the portion of the lengthwise plate portion to which the heat sink is attached, but even when water enters between the control board and the frame from the portion to which the heat sink is attached, the water that is present between the control board and the frame can be guided to the water drainage portions, speedily drained, and prevented from accumulating, because the water guide paths are formed on the lower side of the portion of the lengthwise plate portion to which the heat sink is attached.

An electrical equipment assembly pertaining to a ninth invention comprises the electrical equipment assembly pertaining to the eighth invention, wherein the heat sink is disposed in a position that faces an opening in the partition plate that allows the blower chamber and the machine chamber to be communicated. The water drainage portions are disposed further on a lower side than the opening.

In this electrical equipment assembly, the heat sink is disposed in a position that faces the opening in the partition plate, and it becomes easy for water to adhere also to the lengthwise plate portion of the frame, but because the water drainage portions are disposed further on the lower side than the opening in the partition plate, it becomes difficult for water adhering to the lengthwise plate portion of the frame to enter between the control board and the frame through the water drainage portions.

An electrical equipment assembly pertaining to a tenth invention comprises the electrical equipment assembly pertaining to any of the first to ninth inventions, wherein the water drainage portions are slits.

In this electrical equipment assembly, the water drainage portions are slits, so a drop in the strength of the lower portion of the frame can be prevented as much as possible.

An outdoor unit of an air conditioner pertaining to an eleventh invention comprises a casing, a partition plate that extends vertically so as to divide the inside of the casing into a blower chamber and a machine chamber, and the electrical equipment assembly pertaining to any of the first to tenth inventions that is disposed in the machine chamber.

In this outdoor unit of an air conditioner, the outdoor unit is disposed with the electrical equipment assembly pertaining to any of the first to tenth inventions, so the reliability of the outdoor unit can be improved.

### BRIEF DESCRIPTION OF THE DRAWINGS

FIG. 1 is a plan diagram of an outdoor unit in which an embodiment of an electrical equipment assembly pertaining to the present invention is employed (shown excluding a top plate and refrigerant circuit components other than a compressor, an outdoor heat exchanger and close valves).

FIG. 2 is a front diagram of the outdoor unit (shown excluding left and right front plates and refrigerant circuit components other than the compressor, the outdoor heat exchanger and the close valves).

FIG. 3 is a diagram showing the electrical equipment assembly, in a state where the electrical equipment assembly is disposed inside a machine chamber, as seen from below.

FIG. 4 is a diagram showing the electrical equipment assembly, in a state where the electrical equipment assembly is disposed inside the machine chamber, as seen from the direction of A in FIG. 1.

FIG. 5 is a diagram showing the electrical equipment assembly, in a state where the electrical equipment assembly is disposed inside the machine chamber, as seen from the direction of B in FIG. 1.

FIG. 6 is a diagram showing a board attachment plate of a frame (in a state where a board protection plate, a control board, an inverter control element and a heat sink have been removed) as seen from the direction of A.

FIG. 7 is a cross-sectional diagram along E-E of FIG. 6 (the control board is indicated by a two-dotted chain line).

FIG. 8 is a cross-sectional diagram along F-F of FIG. 6 (the control board is indicated by a two-dotted chain line).

### BEST MODE FOR CARRYING OUT THE INVENTION

Below, an embodiment of an electrical equipment assembly pertaining to the present invention and an outdoor unit of an air conditioner disposed with the electrical equipment assembly will be described.

### (1) Overall Configuration of Outdoor Unit

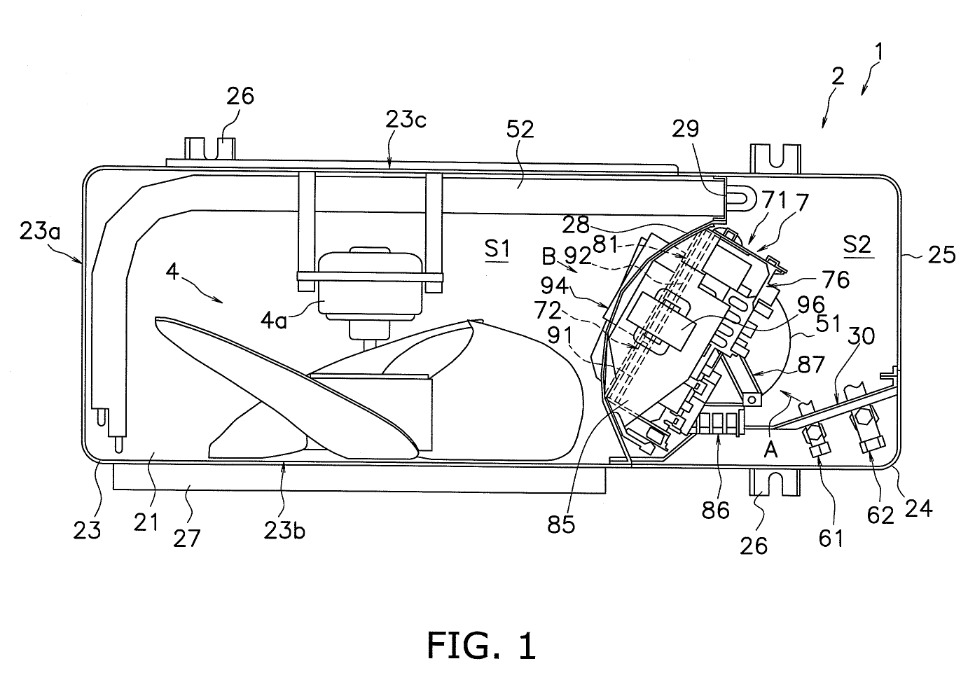

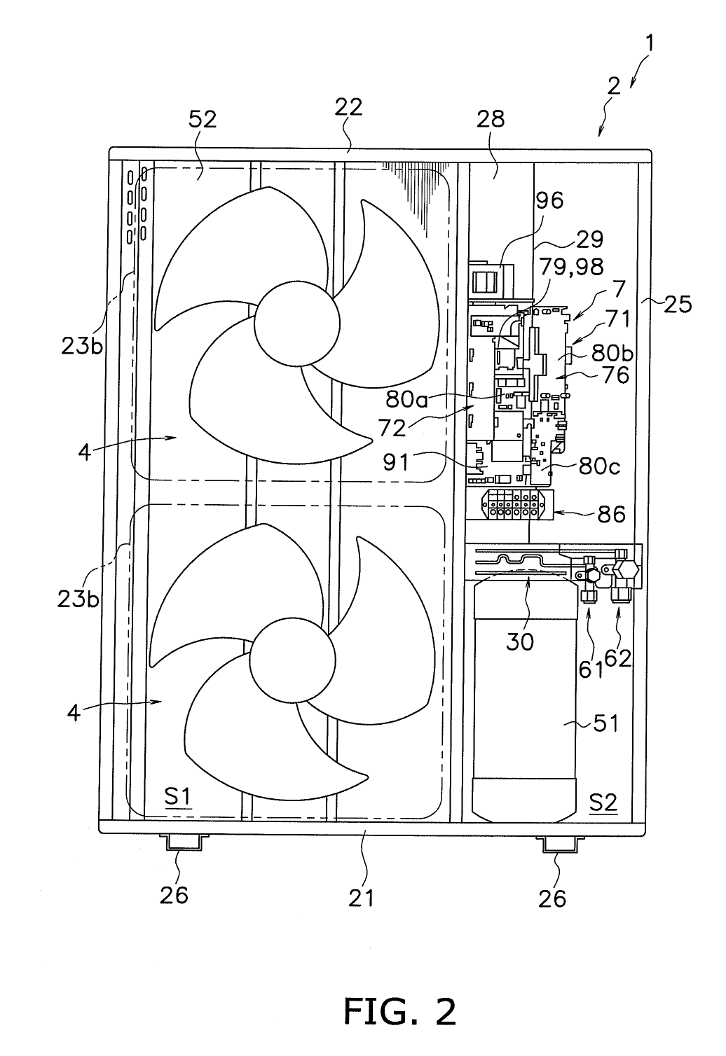

FIG. 1 is a plan diagram of an outdoor unit 1 in which an embodiment of an electrical equipment assembly pertaining to the present invention is employed (shown excluding a top plate 22 and refrigerant circuit components other than a compressor 51, an outdoor heat exchanger 52 and close valves 61 and 62). Further, FIG. 2 is a front diagram of the outdoor unit 1 (shown excluding left and right front plates 23 and 24 and the refrigerant circuit components other than the compressor 51, the outdoor heat exchanger 52 and the close valves 61 and 62).

The outdoor unit 1 is installed outdoors and is called a trunk structure where the inside of a substantially rectangular parallelepiped box-shaped unit casing 2 is divided into a blower chamber S1 and a machine chamber S2 by a partition plate 28 that extends vertically. The outdoor unit 1 is connected via refrigerant pipes (not shown) to an indoor unit (not shown) that is disposed inside an air-conditioned room. The outdoor unit 1 is mainly disposed with the substantially rectangular parallelepiped box-shaped unit casing 2, outdoor fans 4, the refrigerant circuit components that configure a refrigerant circuit and include devices such as the compressor 51 and the outdoor heat exchanger 52, valves such as the liquid close valve 61 and the gas close valve 62 and members such as pipes, and an electrical equipment assembly 7 that performs control of the operation of the outdoor unit 1. It will be noted that, in the following description, “upper”, “lower”, “left”, “right”, “front”, “rear”, “front side” and “rear side” mean, unless otherwise noted, directions when the outdoor unit 1 shown in FIG. 2 is seen from its front side.

### (2) Configuration of Unit Casing

The unit casing 2 mainly includes a bottom plate 21, the top plate 22, the left front plate 23, the right front plate 24 and a right side plate 25.

The bottom plate 21 is a plate-shaped member that is made of metal, has a horizontally long substantially rectangular shape, and configures the bottom surface portion of the unit casing 2. The peripheral edge portion of the bottom plate 21 is bent upward. Two nonretractable legs 26 that are fixed to an on-site installation surface are disposed on the outer surface of the bottom plate 21. The nonretractable legs 26 are plate-shaped members that are made of metal, are substantially U-shaped when the unit casing 2 is seen in the front, and extend from the front side of the unit casing 2 to the rear side.

The top plate 22 is a plate-shaped member that is made of metal, has a horizontally long substantially rectangular shape, and configures the top surface portion of the outdoor unit 1.

The left front plate 23 is a plate-shaped member that is made of metal and mainly configures the left front surface portion and the left side surface portion of the unit casing 2, and the lower portion of the left front plate 23 is fixed to the bottom plate 21 by screws or the like. Suction openings 23a, through which air is sucked into the inside of the unit casing 2 by the outdoor fans 4, are formed in the left front plate 23. Further, blowout openings 23b for blowing out, to the outside, air that has been taken into the inside from the rear surface side and the left side surface side of the unit casing 2 by the outdoor fans 4 are disposed in the left front plate 23. A total of two upper and lower blowout openings 23b are formed, and fan grilles 27 are respectively disposed in the blowout openings 23b.

The right front plate 24 is a plate-shaped member that is made of metal and mainly configures the right front surface portion and the front portion of the right side surface of the unit casing 2, and the lower portion of the right front plate 24 is fixed to the bottom plate 21 by screws or the like. Further, the left end portion of the right front plate 24 is fixed to the right end portion of the left front plate 23 by screws or the like.

The right side plate 25 is a plate-shaped member that is made of metal and mainly configures the rear portion of the right side surface and the right rear surface portion of the unit casing 2, and the lower portion of the right side plate 25 is fixed to the bottom plate 21 by screws or the like. Additionally, suction openings 23c, through which air is sucked into the inside of the unit casing 2 by the outdoor fans 4, are formed between the rear end portion of the left front plate 23 and the rear surface side end portion of the right side plate 25 in the left-right direction.

Inside the unit casing 2 are disposed the partition plate 28 and a tube plate 29. The partition plate 28 is a plate-shaped member that is made of metal, is disposed on the bottom plate 21 and extends vertically. The partition plate 28 is disposed so as to partition the inside of the unit casing 2 into two spaces: a space on the left and a space on the right. In the present embodiment, the partition plate 28 has a curved shape that projects toward the blower chamber S1 when the unit casing 2 is seen in a plan view. The tube plate 29 is a plate-shaped member that is made of metal and is disposed so as to face the right end surface of the substantially L-shaped outdoor heat exchanger 52 that is disposed so as to follow the left side surface of the unit casing 2 to the rear surface, and the lower portion of the tube plate 29 is fixed to the bottom plate 21 by screws or the like. Additionally, the end portion of the tube plate 29 on the unit casing front surface side and the end portion of the partition plate 28 on the unit casing rear surface side are fixed to each other by screws or the like. Further, the right end portion of the left front plate 23 is fixed to the front end portion of the partition plate 28 by screws or the like. The end portion of the right side plate 25 on the rear surface side is fixed to the end portion of the tube plate 29 on the unit casing rear surface side by screws or the like.

In this manner, the inside of the unit casing 2 is divided into the blower chamber S1 and the machine chamber S2 by the partition plate 28. More specifically, the blower chamber S1 is a space enclosed by the bottom plate 21, the top plate 22, the left front plate 23 and the partition plate 28, and mainly the outdoor fans 4 and the outdoor heat exchanger 52 are disposed in the blower chamber S1. The machine chamber S2 is a space enclosed by the bottom plate 21, the top plate 22, the right front plate 24, the right side plate 25 and the partition plate 28, and mainly the refrigerant circuit components, other than the outdoor heat exchanger 52, and the electrical equipment assembly 7 are disposed in the machine chamber S2. Additionally, the unit casing 2 is configured such that the inside of the machine chamber S2 may be seen by removing the right front plate 24. That is, the right front plate 24 is removed when performing on-site work such as maintenance of the refrigerant circuit components and the electrical equipment assembly 7 that are housed inside the machine chamber S2 of the outdoor unit 1.

### (3) Configuration of Outdoor Fans

The outdoor fans 4 are propeller fans that include plural blades and are disposed on the front side of the outdoor heat exchanger 52 inside the blower chamber S1. In the present embodiment, a total of two of the outdoor fans 4 are disposed in the upper area and the lower area inside the blower chamber S1 such that the outdoor fans 4 face the blowout openings 23b. The outdoor fans 4 are configured such that they are driven to rotate by outdoor fan motors 4a. When the outdoor fans 4 are driven, air is taken into the inside through the suction openings 23a and 23c in the rear surface and the left side surface of the unit casing 2, passes through the outdoor heat exchanger 52, and is thereafter blown out to the outside of the unit casing 2 from the blowout openings 23b in the front surface of the unit casing 2.

### (4) Configuration of Refrigerant Circuit Components

The compressor 51 is a hermetic compressor that houses a compressor motor inside a housing, and the compressor 51 is disposed inside the machine chamber S2. Here, the compressor motor is a so-called inverter type of motor whose frequency is capable of being controlled by the electrical equipment assembly 7. In the present embodiment, the compressor 51 has an upright circular cylinder shape with a height of about ⅓ to ½ the entire height of the unit casing 2, and the lower portion of the compressor 51 is fixed to the bottom plate 21. Further, when the unit casing 2 is seen in a plan view, the compressor 51 is disposed in the vicinity of the center of the machine chamber S2 in the front-rear direction and in the vicinity of the partition plate 28 in the machine chamber S2.

The outdoor heat exchanger 52 is disposed inside the blower chamber S1 and performs heat exchange with air that has been taken into the inside of the unit casing 2 by the outdoor fans 4. The outdoor heat exchanger 52 is substantially L-shaped when the unit casing 2 is seen in a plan view and is disposed so as to follow the left side surface of the unit casing 2 to the rear surface.

The liquid close valve 61 and the gas close valve 62, to which refrigerant pipes of the indoor unit are connected, are disposed inside the unit casing 2. More specifically, the liquid close valve 61 and the gas close valve 62 are disposed in positions facing the right front plate 24 in the front portion of the machine chamber S2. In the present embodiment, the liquid close valve 61 and the gas close valve 62 are supported on a long and narrow plate-shaped close valve support member 30 that is disposed so as to span the distance between the right end portion of the left front plate 23 and the front end portion of the right side plate 25. The close valve support member 30 is disposed in a height position in the vicinity of the upper end of the compressor 51 inside the machine chamber S2.

### (5) Configuration of Electrical Equipment Assembly

The electrical equipment assembly 7 includes various types of electrical parts such as a control board 91, on which operation control elements for performing operation control are mounted, and an inverter control element 92. In the present embodiment, the electrical equipment assembly 7 is disposed in the vicinity of the partition plate 28 in the upper portion of the machine chamber S2. The electrical equipment assembly 7 mainly includes a frame 71, a terminal block 86 and a terminal block support member 87.

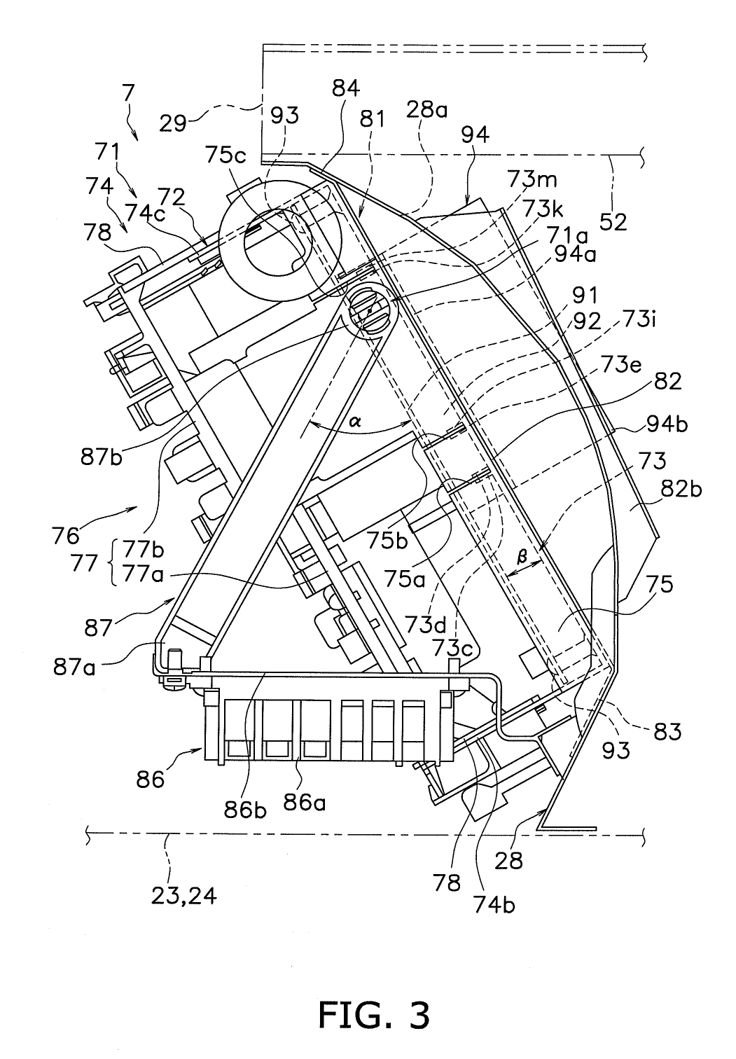

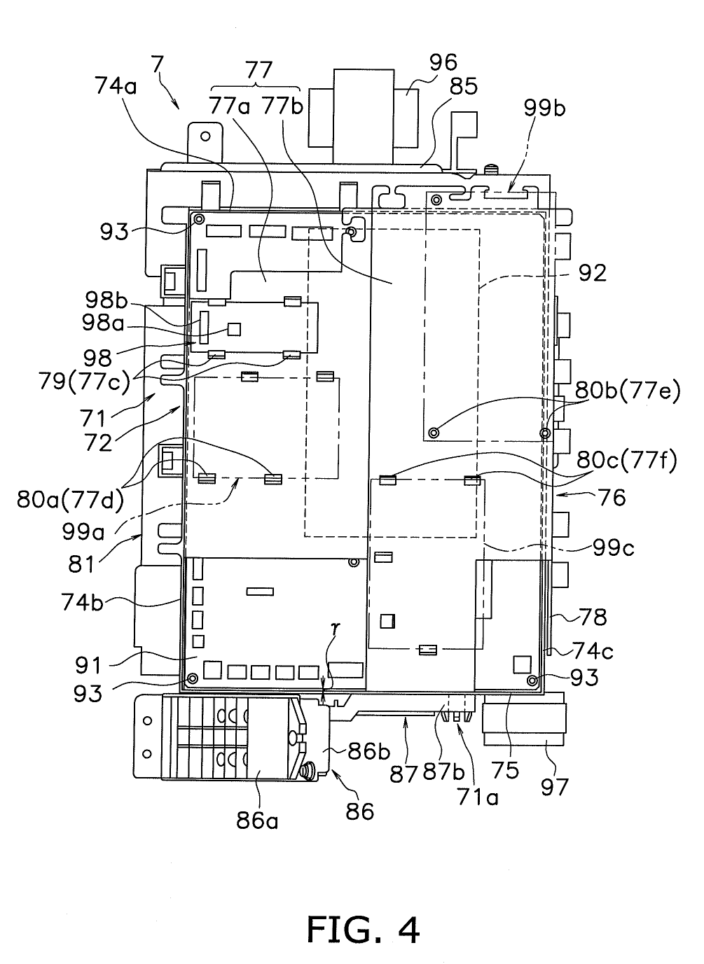

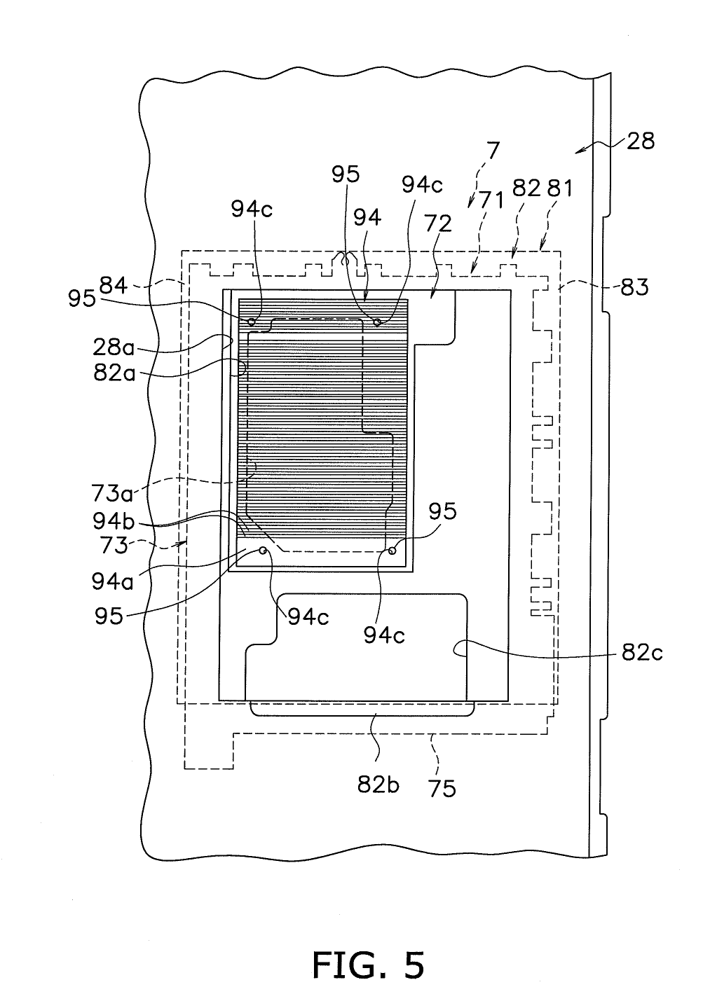

Next, the configuration of the electrical equipment assembly 7 will be described in detail using FIGS. 3 to 6. Here, FIG. 3 is a diagram showing the electrical equipment assembly 7, in a state where the electrical equipment assembly 7 is disposed inside the machine chamber S2, as seen from below. FIG. 4 is a diagram showing the electrical equipment assembly 7, in a state where the electrical equipment assembly 7 is disposed inside the machine chamber S2, as seen from the direction of A in FIG. 1. FIG. 5 is a diagram showing the electrical equipment assembly 7, in a state where the electrical equipment assembly 7 is disposed inside the machine chamber S2, as seen from the direction of B in FIG. 1.

The frame 71 is a substantially rectangular parallelepiped box-shaped member that is made of resin and to which various types of electrical parts, including the control board 91 on which the operation control elements are mounted and the inverter control element 92, are attached. The frame 71 mainly includes a board attachment plate 72, to which various types of electrical parts including the control board 91 and the inverter control element 92 are attached, and a board protection plate 76, which covers the control board 91.

The board attachment plate 72 is a member that is disposed on the blower chamber S1 side in a state where the electrical equipment assembly 7 is disposed inside the machine chamber S2. The board attachment plate 72 mainly includes an attachment plate portion 73, which serves as a lengthwise plate portion that slants with respect to the front surface of the unit casing 2 (that is, the front surface portions of the left and right front plates 23 and 24) and extends vertically, and an attachment frame portion 74, which extends toward the opposite side of the blower chamber S1 side from the outer peripheral edge of the attachment plate portion 73. An attachment plate opening 73a is formed in the substantial center of the attachment plate portion 73 when seen from the direction of arrow A or arrow B. Additionally, the inverter control element 92 is attached to the surface of the attachment plate portion 73 on the opposite side of the blower chamber S1 side and in a position that faces the attachment plate opening 73a. The inverter control element 92 is an electrical part that emits high-temperature heat during operation, such as a power transistor or a diode, for example. Further, on the opposite side of the blower chamber S1 side of the attachment plate portion 73, the control board 91, on which the operation control elements are mounted, is attached using plural screws 93 that serve as fixing members in a state where the control board 91 is parallel to the surface of the attachment plate portion 73. That is, similar to the attachment plate portion 73, the board surface of the control board 91 slants with respect to the front surface of the unit casing 2 and extends vertically. Further, the control board 91 is disposed in a state where there is a clearance (below, this clearance will be called a clearance β) between the control board 91 and the surface of the attachment plate portion 73 on the opposite side of the blower chamber S1 side. In the present embodiment, this clearance β is 5 mm to 20 mm. Moreover, in the present embodiment, the control board 91 is disposed such that the inverter control element 92 is interposed between the control board 91 and the surface of the attachment plate portion 73 on the opposite side of the blower chamber S1 side, and the control board 91 is integrated with the inverter control element 92. Further, a heat sink 94 is attached to the surface of the attachment plate portion 73 on the blower chamber S1 side so as to cover the attachment plate opening 73a. The heat sink 94 mainly includes a flange portion 94a, which is attached to the surface of the attachment plate portion 73 on the blower chamber S1 side, and horizontal plural cooling fins 94b, which project into the inside of the blower chamber S1 from the surface of the flange portion 94a on the blower chamber S1 side. The flange portion 94a is a substantially rectangular plate portion. The attachment frame portion 74 is mainly configured by an upper frame portion 74a that extends substantially horizontally toward the opposite side of the blower chamber S1 side from the upper edge portion of the attachment plate portion 73, side frame portions 74b and 74c that extend substantially horizontally toward the opposite side of the blower chamber S1 side from the side edge portions of the attachment plate portion 73, and a lower frame portion 75 that serves as a sideways plate portion that extends substantially horizontally toward the opposite side of the blower chamber S1 side from the lower edge portion of the attachment plate portion 73. Additionally, the control board 91 is disposed on the inner side of the attachment frame portion 74 such that there is a slight clearance (below, this clearance will be called a clearance γ) between the control board 91 and the attachment frame portion 74. In the present embodiment, this clearance γ is equal to or less than 3 mm (e.g., see the vertical direction clearance γ between the lower frame portion 75 and the control board 91 in FIG. 4). Further, plural (here, three) slits 75a to 75c that serve as water drainage portions are formed in the lower frame portion 75. In the present embodiment, each of the slits 75a to 75c extends from the interconnecting portion of the attachment plate portion 73 and the lower frame portion 75 and cuts across the lower side of the control board 91 as far as the end portion of the lower frame portion 75 on the opposite side of the blower chamber S1 side.

The board protection plate 76 is a member that is disposed on the opposite side of the blower chamber S1 side of the board attachment plate 72 in a state where the electrical equipment assembly 7 is disposed inside the machine chamber S2. The board protection plate 76 mainly includes a protective plate portion 77, which slants with respect to the front surface of the unit casing 2 (that is, the front surface portions of the left and right front plates 23 and 24) and extends vertically, and a protective frame portion 78, which extends toward the blower chamber S1 from the outer peripheral edge of the protective plate portion 77. The protective plate portion 77 mainly includes a front side protective plate portion 77a, which is toward the front surface of the unit casing 2 in a state where the electrical equipment assembly 7 is disposed inside the machine chamber S2, and a rear side protective plate portion 77b, which is farther than the front side protective plate portion 77a from the front surface of the unit casing 2. The rear side protective plate portion 77b is integrated in a state where it projects in the direction of arrow B with respect to the front side protective plate portion 77a via a step that is formed in the substantial center in the left-right direction of the protective plate portion 77 when seen from the direction of arrow A. The front side protective plate portion 77a and the rear side protective plate portion 77b are disposed parallel to the surface of the attachment plate portion 73. The protective frame portion 78 is disposed such that, when seen from a direction orthogonal to the direction of arrow A or arrow B, the mutual end portions of the protective frame portion 78 and the attachment frame portion 74 in the direction of arrow A or arrow B are superposed. Additionally, the board protection plate 76 is attached to the board attachment plate 72 using screws or engagement claws that are formed on the protective frame portion 78 or the attachment frame portion 74 (specifically, the upper frame portion 74a, the side frame portions 74b and 74c, and the lower frame portion 75). Further, a first auxiliary board 98, on which high-access-frequency control elements (e.g., a display element 98a that comprises an LED or the like and an operation element 98b that comprises a switch and a connector) that require visibility and serviceability of operation control elements are mounted, is attached, separately from the control board 91, to the outer surface of the front side protective plate portion 77a (that is, the surface when the board protection plate 76 is seen from the direction of arrow A). Here, the first auxiliary board 98 is fixed in a first auxiliary board attachment portion 79 that includes plural (here, four) engagement claws 77c that are formed on the outer surface of the front side protective plate portion 77a. Moreover, in a state where the electrical equipment assembly 7 is disposed inside the machine chamber S2, second auxiliary boards 99a, 99b and 99c, on which added function control elements that are required when adding additional functions (e.g., a communication function and a demand control function) are mounted, can be respectively attached to the lower side of the first auxiliary board attachment portion 79 of the front side protective plate portion 77a, the upper portion of the rear side protective plate portion 77b and the lower portion of the rear side protective plate portion 77b. Here, the second auxiliary board 99a can be fixed in a second auxiliary board attachment portion 80a that includes plural (here, four) engagement claws 77d that are formed on the outer surface of the front side protective plate portion 77a. The second auxiliary board 99b can be fixed in a second auxiliary board attachment portion 80b that includes plural (here, three) screw holes 77e that are formed in the outer surface of the rear side protective plate portion 77b. The second auxiliary board 99c can be fixed in a second auxiliary board attachment portion 80c that includes plural (here, three) engagement claws 77f that are formed in the outer surface of the rear side protective plate portion 77b. It will be noted that, even when the frame 71 (that is, the board protection plate 76) is seen from the direction of arrow A, the frame 71 does not end up being hidden by the side surface of the unit casing 2 (that is, the side surface portion of the right front plate 24 and the side surface portion of the right side plate 25), and the frame 71 slants with respect to the front surface of the unit casing 2 such that all of the high-access-frequency control elements 98a and 98b (that is, all of the first auxiliary board 98) can be seen. More specifically, the frame 71 slants with respect to the front surface of the unit casing 2 such that, when the frame 71 (that is, the board protection plate 76) is seen from the direction of arrow A, the front end of the side surface of the unit casing 2 is almost superposed with the step that extends in the vertical direction of the board protection plate 76.

Further, in a state where the electrical equipment assembly 7 is disposed inside the machine chamber S2, a reactor 96 is attached to the top surface of the frame 71 via a reactor attachment plate 85 that is made of metal, and a noise filter 97 is attached to the undersurface of the frame 71.

Additionally, a frame support plate 81 is fixed to the frame 71, to which the aforementioned various types of electrical parts and the heat sink 94 are attached, so as to cover the surface of the attachment plate portion 73 on the blower chamber S1 side. The frame support plate 81 is a member that is made of metal and mainly includes a support plate portion 82, which contacts the surface of the attachment plate portion 73 on the blower chamber S1 side, and a front side extension portion 83 and a rear side extension portion 84, which extend along the curved surface of the partition plate 28 from both side edges of the support plate portion 82 in a state where the electrical equipment assembly 7 is disposed inside the machine chamber S2. Here, the support plate portion 82 covers almost the entire surface of the attachment plate portion 73 excluding the lower portion of the attachment plate portion 73, and a support plate opening 82a is formed in the support plate portion 82 so as to surround the outer peripheral side of the flange portion 94a of the heat sink 94 that is attached to the attachment plate portion 73. Thus, the plural cooling fins 94b of the heat sink 94 that is attached to the frame 71 pass through the support plate opening 82a and project toward the blower chamber S1 side of the support plate portion 82 in a state where the frame 71 is fixed to the frame support plate 81. Further, a tongue portion 82b, whose lower end extends toward the blower chamber S1 and thereafter extends downward, is formed, by bending or the like, in the support plate portion 82. Additionally, the frame support plate 81 is fixed to the partition plate 28 using screws or engagement claws that are formed on the front side extension portion 83, the rear side extension portion 84 or the support plate portion 82, for example, in a state where the frame 71 is fixed. Here, a substantially rectangular partition plate opening 28a is formed in the partition plate 28 so as to allow the blower chamber S1 and the machine chamber S2 to be communicated. The partition plate opening 28a is formed so as to face the support plate opening 82a and surround the support plate opening 82a and the lower end of the support plate portion 82 when seen from the direction of arrow B. Thus, the plural cooling fins 94b of the heat sink 94 and the tongue portion 82b of the frame support plate 81 project into the inside of the blower chamber S1 in a state where the frame 71 is fixed to the partition plate 28 via the frame support plate 81 and can perform cooling during operation of the inverter control element 92. Further, the frame 71 is disposed such that, in a state where the frame 71 is disposed inside the machine chamber S2, the board surface of the control board 91 follows the partition plate 28 and slants with respect to the front surface of the unit casing 2. Moreover, corner portions of the frame 71 contact the curved surface of the partition plate 28 via the frame support plate 81 so as to follow the curved surface of the partition plate 28 when the electrical equipment assembly 7, in a state where the electrical equipment assembly 7 is disposed inside the machine chamber S2, is seen from above.

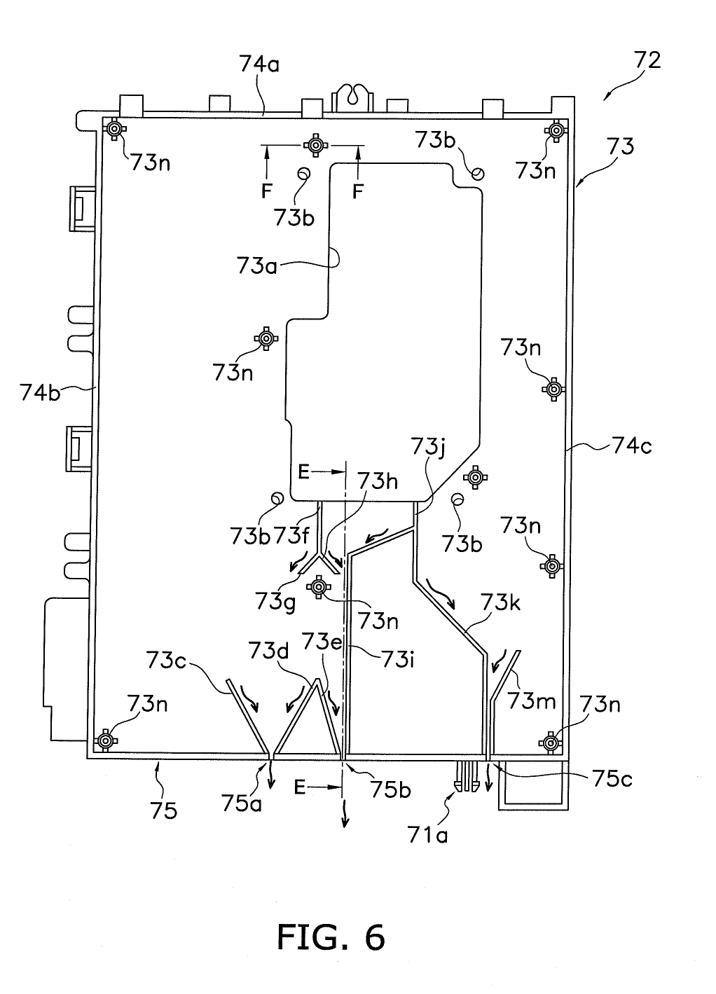

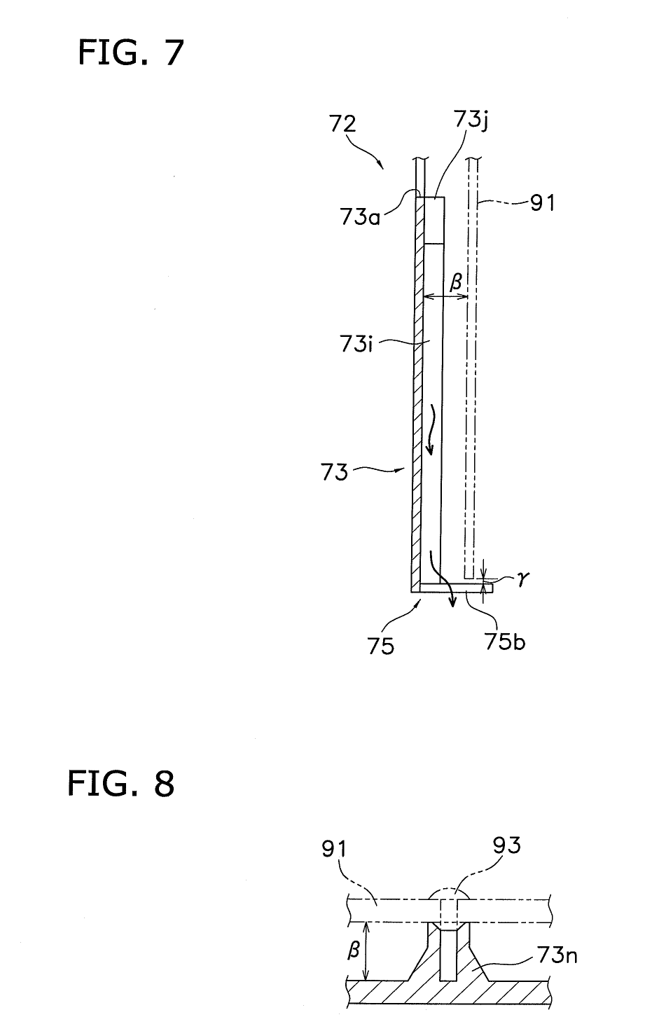

Additionally, water guide paths (specifically, water guide paths that are configured by plural water guide ribs 73c to 73k and 73m that serve as projecting portions described below) that guide water that is present between the control board 91 and the attachment plate portion 73 to the plural slits 75a to 75c that serve as the water drainage portions are formed in the surface of the attachment plate portion 73 on the opposite side of the blower chamber S1 side (that is, the surface that faces the board surface of the control board 91), so that even when water enters between the control board 91 and the attachment plate portion 73, the water that is present between the control board 91 and the frame 71 can be speedily drained and prevented from accumulating. Below, the water guide paths, including their peripheral structure, will be described in detail using FIGS. 3 and 5 to 8. Here, FIG. 6 is a diagram showing the board attachment plate 72 of the frame 71 (in a state where the board protection plate 76, the control board 91, the inverter control element 92 and the heat sink 94 have been removed) as seen from the direction of A. FIG. 7 is a cross-sectional diagram along E-E of FIG. 6 (the control board 91 is indicated by a two-dotted chain line). FIG. 8 is a cross-sectional diagram along F-F of FIG. 6 (the control board 91 is indicated by a two-dotted chain line).

First, the structure by which the control board 91 is attached to the attachment plate portion 73 will be described in detail. As shown in FIGS. 6 and 8, plural (here, ten) fixed seat portions 73n for attaching the control board 91 to the attachment plate portion 73 are formed on the surface of the attachment plate portion 73 on the opposite side of the blower chamber S1 side, such that the fixed seat portions 73n project toward the control board. A flat surface that abuts against the board surface of the control board 91 is formed on the end portion of each of the fixed seat portions 73n on the control board side, and when the control board 91 is to be attached to the attachment plate portion 73, the control board 91 is disposed in a state where it is parallel to the surface of the attachment plate portion 73 and in a state where there is the clearance β between the control board 91 and the surface of the attachment plate portion 73 on the opposite side of the blower chamber S1 side. Additionally, screw holes that extend toward the attachment plate portion 73 side from the end portions of the fixed seat portions 73n on the control board side are formed in the fixed seat portions 73n, and the control board 91 is attached using the screws 93. Further, in a state where the control board 91 has been attached to the attachment plate portion 73 using the screws 93, the control board 91 is disposed on the inner side of the attachment frame portion 74 (the upper side of the lower frame portion 75) such that there is the clearance γ between the control board 91 and the lower frame portion 75.

Next, the structure by which the flange portion 94a of the heat sink 94 is attached to the attachment plate portion 73 will be described in detail. The flange portion 94a is attached to the attachment plate portion 73 using screws 95. More specifically, as shown in FIG. 6, plural (here, four) screw holes 73b, into which the screws 95 are inserted, are formed in the attachment plate portion 73 on the outer peripheral side of the attachment plate opening 73a. Further, as shown in FIG. 5, screws holes 94c are formed in the flange portion 94a in positions that correspond to the screw holes 73b, and the screws 95 are inserted into both of the screw holes 73b and 94c, whereby the flange portion 94a is attached to the attachment plate portion 73.

Next, the slits 75a to 75c that serve as the drainage portions will be described in detail. As shown in FIG. 6, the slit 75a is formed in a position toward the side frame portion 74b of the lower frame portion 75 when the lower frame portion 75 is seen from the direction of A. Further, speaking in terms of its relationship with the portion where the attachment plate opening 73a and the screw holes 73b are formed (that is, the portion to which the heat sink 94 is attached), the slit 75a is disposed on the lower side of the portion toward the side frame portion 74b of the portion to which the heat sink 94 is attached. As shown in FIG. 6, the slit 75b is formed in a position in the substantial center in the transverse direction of the lower frame portion 75 when the lower frame portion 75 is seen from the direction of A. Further, speaking in terms of its relationship with the portion where the attachment plate opening 73a and the screw holes 73b are formed (that is, the portion to which the heat sink 94 is attached), the slit 75b is disposed on the lower side of the portion in the substantial center in the transverse direction of the portion to which the heat sink 94 is attached. As shown in FIG. 6, the slit 75c is formed in a position toward the side frame portion 74c of the lower frame portion 75 when the lower frame portion 75 is seen from the direction of A. Further, speaking in terms of its relationship with the portion where the attachment plate opening 73a and the screw holes 73b are formed (that is, the portion to which the heat sink 94 is attached), the slit 75c is disposed on the lower side of the portion toward the side frame portion 74c of the portion to which the heat sink 94 is attached. Moreover, as shown in FIG. 5, the lower end portions of the lower frame portion 75 and the attachment plate portion 73 are disposed further on the lower side than the partition plate opening 28a in the partition plate 28, so the slits 75a to 75c that are formed in the lower frame portion 75 are also disposed further on the lower side than the partition plate opening 28a.

Next, the water guide ribs 73c to 73k and 73m that are formed on the surface of the attachment plate portion 73 on the opposite side of the blower chamber S1 side will be described in detail. As shown in FIG. 6, the water guide rib 73c extends, when the attachment plate portion 73 is seen from the direction of A, straight diagonally downward from a position that is on the upper side of the slit 75a and on the side frame portion 74b side of the slit 75a toward the edge portion of the slit 75a on the side frame portion 74b side. Here, the lower end of the water guide rib 73c is connected to the edge portion of the slit 75a on the side frame portion 74b side and is integrated with the top surface of the lower frame portion 75. As shown in FIG. 6, the water guide rib 73d extends, when the attachment frame portion 73 is seen from the direction of A, straight diagonally downward from a position that is on the upper side of the slit 75a and on the side frame portion 74c side of the slit 75a toward the edge portion of the slit 75a on the side frame portion 74c side. Here, the lower end of the water guide rib 73d is connected to the edge portion of the slit 75a on the side frame portion 74c side and is integrated with the top surface of the lower frame portion 75. As shown in FIG. 6, the water guide rib 73e extends, when the attachment frame portion 73 is seen from the direction of A, straight diagonally downward from a position that is on the upper side of the slit 75b and on the side frame portion 74b side of the slit 75b toward the edge portion of the slit 75b on the side frame portion 74b side. Here, the lower end of the water guide rib 73e is connected to the edge portion of the slit 75b on the side frame portion 74b side and is integrated with the top surface of the lower frame portion 75. Further, the upper end portion of the water guide rib 73e is connected to the upper end portion of the water guide rib 73d. As shown in FIG. 6, the water guide rib 73f extends, when the attachment plate portion 73 is seen from the direction of A, straight vertically downward from the lower edge portion of the attachment plate opening 73a toward the fixed seat portion 73n that is disposed below the lower edge portion of the attachment plate opening 73a. Here, the water guide rib 73f does not extend to an extent that it abuts against the fixed seat portion 73n, but rather extends as far as a position directly above the fixed seat portion 73n. As shown in FIG. 6, the water guide rib 73g extends, when the attachment plate portion 73 is seen from the direction of A, straight diagonally downward from the lower end portion of the water guide rib 73f as far as a position further toward the side frame portion 74b than the edge portion, on the side frame portion 74b side, of the fixed seat portion 73n that is directly below the lower end portion of the water guide rib 73f. Here, the lower end portion of the water guide rib 73g extends as far as a position that corresponds to above the slit 75a or the water guide rib 73d. As shown in FIG. 6, the water guide rib 73h extends, when the attachment plate portion 73 is seen from the direction of A, straight diagonally downward from the lower end portion of the water guide rib 73f as far as a position further toward the side frame portion 74c than the edge portion, on the side frame portion 74c side, of the fixed seat portion 73n that is directly below the lower end portion of the water guide rib 73f. Here, the lower end portion of the water guide rib 73h extends as far as a position that corresponds to above the slit 75b or the water guide rib 73e. As shown in FIG. 6, the water guide rib 73j extends, when the attachment plate portion 73 is seen from the direction of A, straight vertically downward from a position that is on the lower edge portion of the attachment plate opening 73a and further toward the side frame portion 74c than the water guide rib 73f as far as a position where the water guide rib 73j branches into the water guide rib 73i and the water guide rib 73k that will be described later. As shown in FIG. 6, the water guide rib 73i extends, when the attachment plate portion 73 is seen from the direction of A, straight diagonally downward from the lower end portion of the water guide rib 73j toward the edge portion of the slit 75b on the side frame portion 74c side and then extends straight vertically downward. Here, the lower end of the water guide rib 73i is connected to the edge portion of the slit 75b on the side frame portion 75c side and is integrated with the top surface of the lower frame portion 75. As shown in FIG. 6, the water guide rib 73k extends, when the attachment plate portion 73 is seen from the direction of A, straight vertically downward from the lower end portion of the water guide rib 73j and then extends straight diagonally downward and then extends straight vertically downward toward the edge portion of the slit 75c on the side frame portion 74b side. Here, the lower end of the water guide rib 73k is connected to the edge portion of the slit 75c on the side frame portion 74b side and is integrated with the top surface of the lower frame portion 75. As shown in FIG. 6, the water guide rib 73m extends, when the attachment plate portion 73 is seen from the direction of A, straight diagonally downward from a position that is on the upper side of the slit 75c and on the side frame portion 74c side of the slit 75c and then extends straight vertically downward toward the edge portion of the slit 75c on the side frame portion 74c side. Here, the lower end of the water guide rib 73m is connected to the edge portion of the slit 75c on the side frame portion 74c side and is integrated with the top surface of the lower frame portion 75.

As shown in FIGS. 6 and 7, the water guide ribs 73c to 73k and 73m are disposed on the lower side of the portion where the heat sink 94 is attached to the attachment plate portion 73 (that is, the attachment plate opening 73a and the screw holes 73b). Further, the distance to which the water guide ribs 73c to 73k and 73m project toward the control board is set to be equal to or less than the clearance β between the control board 91 and the surface of the attachment plate portion 73 on the opposite side of the blower chamber S1 side.

Additionally, the water guide ribs 73c to 73k and 73m configure the water guide paths which, when water is present between the control board 91 and the attachment plate portion 73, guide the water to the slits 75a to 75c (see the arrows that have been added to the water guide ribs and their vicinities in FIGS. 6 and 7). More specifically, the water guide ribs 73c and 73d configure a water guide path that receives water flowing down from above and guides the water to the slit 75a. The water guide ribs 73e and 73i configure a water guide path that receives water flowing down from above and guides the water to the slit 75b. The water guide ribs 73k and 73m configure a water guide path that receives water flowing down from above and guides the water to the slit 75c. The water guide ribs 73f to 73h configure water guide paths that receive water flowing down from above and guide the water to the slits 75a and 75b that are further on the lower side than the water guide ribs 73g and 73h while avoiding the fixed seat portion 73n that is formed directly below the water guide rib 73f.

In this manner, in the electrical equipment assembly 7 of the present embodiment, the plural slits 75a to 75c that serve as the water drainage portions that drain water that is present between the control board 91 and the attachment plate portion 73 are formed in the lower portion of the board attachment plate 72 that configures the frame 71 (here, the lower frame portion 75 that serves as the sideways plate portion), and the plural water guide ribs 73c to 73k and 73m that serve as the projecting portions that configure the water guide paths for guiding the water to the plural slits 75a to 75c are formed on the surface of the attachment plate portion 73 on the opposite side of the blower chamber S1 side (that is, the surface that faces the board surface of the control board 91). Additionally, the slits 75a to 75c and the water guide ribs 73c to 73k and 73m are formed at the same time when the board attachment plate 72 is resin-injection-molded.

The terminal block 86 mainly includes a terminal block body 86a, which includes plural terminal portions for power source connection, and a terminal block fixing plate 86b, to which the rear surface of the terminal block body 86a is fixed. In a state where the electrical equipment assembly 7 is disposed inside the machine chamber S2, the terminal block 86 is disposed such that the terminal portions of the terminal block body 86a face the front surface of the unit casing 2, and one end of the terminal block fixing plate 86b on the partition plate 28 side is fixed to the partition plate 28. It will be noted that the one end of the terminal block fixing plate 86b may also be fixed to the front portion of the left front plate 23.

The terminal block support member 87 is a bar-shaped member that includes a first terminal block support portion 87a, which supports the terminal block 86 in a state where the electrical equipment assembly 7 is disposed inside the machine chamber S2, and a frame-supported portion 87b, which is supported such that the frame-supported portion 87b is rotatable around an engagement shaft 71a (whose axial center is O) that is a shaft that extends in the vertical direction of the frame 71 in a state where the electrical equipment assembly 7 is disposed inside the machine chamber S2. The first terminal block support portion 87a of the terminal block support member 87 is capable of being moved toward or away from the board surface of the control board 91 as a result of the frame-supported portion 87b being rotated. Additionally, the other end of the terminal block fixing plate 86b is supported as a result of being attached to the first terminal block support portion 87a in a first state where the terminal block support member 87 is slanted by an angle α.

In this manner, in the electrical equipment assembly 7 of the present embodiment, the terminal block 86 is, separately from the frame 71, fixed to the partition plate 28 such that the terminal block 86 faces the front surface of the unit casing 2, and the terminal block 86 is supported by the terminal block support member 87 that is disposed on the frame 71.

### (6) Characteristics of Electrical Equipment Assembly of Present Embodiment and Outdoor Unit Disposed with the Electrical Equipment Assembly

The electrical equipment assembly 7 of the present embodiment and the outdoor unit 1 disposed with the electrical equipment assembly 7 has the following characteristics.

### (A)

In the electrical equipment assembly 7 of the present embodiment and the outdoor unit 1 disposed with the electrical equipment assembly 7, the frame 71 holds the control board 91 that is disposed lengthwise, the slits 75a to 75c that serve as the water drainage portions that drain water that is present between the frame 71 and the control board 91 are formed in the lower portion of the frame 71, and the water guide ribs 73c to 73k and 73m that configure the water guide paths that guide the water to the slits 75a to 75c are formed in the surface of the frame 71 that faces the board surface of the control board 91 (in the present embodiment, the surface on the opposite side of the blower chamber S1 side), so water that is present between the control board 91 and the frame 71 (more specifically, the attachment plate portion 73) can be speedily drained and prevented from accumulating. Thus, in this electrical equipment assembly 7, it can be made difficult for problems to occur even when water enters between the control board 91 and the frame 71, such as the water contacting the pattern on the control board 91 and the control board 91 short-circuiting, and the reliability of the electrical equipment assembly 7 can be improved. As a result, the reliability of the outdoor unit 1 can also be improved.

Further, in the electrical equipment assembly 7 of the present embodiment, the water drainage portions are the slits 75a to 75c, so a drop in the strength of the lower portion of the frame 71 can be prevented as much as possible.

### (B)

In the electrical equipment assembly 7 of the present embodiment, the water guide ribs 73c to 73k and 73m that configure the water guide paths are disposed on the upper side of the slits 75a to 75c that serve as the water drainage portions, so water entering between the control board 91 and the frame 71 (more specifically, the attachment plate portion 73) can be guided by the force of gravity to the plural slits 75a to 75c.

### (C)

In the electrical equipment assembly 7 of the present embodiment, the frame 71 includes the attachment plate portion 73 that serves as the lengthwise plate portion that faces the board surface of the control board 91 and the lower frame portion 75 that serves as the sideways plate portion that extends sideways from the surface of the attachment plate portion 73 on the control board side (in the present embodiment, the surface on the opposite side of the blower chamber S1 side) such that the lower frame portion 75 is positioned on the lower side of the control board 91. When water enters between the control board 91 and the frame 71 (more specifically, the attachment plate portion 73), it becomes easy for the water to accumulate in the interconnecting portion of the attachment plate portion 73 and the lower frame portion 75 and in the vicinity of that interconnecting portion, but because the water guide ribs 73c to 73k and 73m that configure the water guide paths are formed in the attachment plate portion 73 that configures the surface that faces the board surface of the control board 91, the water that is present between the control board 91 and the frame 71 can be guided to the plural slits 75a to 75c that serve as water drainage portions, speedily drained, and prevented from accumulating in the interconnecting portion of the attachment plate portion 73 and the lower frame portion 75 and in the vicinity of that interconnecting portion.

### (D)

In the electrical equipment assembly 7 of the present embodiment, the vertical direction clearance γ between the lower frame portion 75 that serves as the sideways plate portion and the control board 91 is equal to or less than 3 mm. When water enters between the control board 91 and the frame 71 (more specifically, the attachment plate portion 73), it becomes easy for the water to accumulate in the portion between the lower frame portion 75 and the control board 91 and in the vicinity of that portion because the sideways plate portion and the control board are disposed in extremely close proximity to each other, but because the water guide ribs 73c to 73k and 73m that serve as the water guide paths and the slits 75a to 75c that serve as the water drainage portions are formed, the water that is present between the control board 91 and the frame 71 can be guided to the slits 75a to 75c by the water guide ribs 73c to 73k and 73m, speedily drained, and prevented from accumulating in the portion between the lower frame portion 75 and the control board 91 and in the vicinity of that portion.

### (E)

In the electrical equipment assembly 7 of the present embodiment, when water enters between the control board 91 and the frame 71 (more specifically, the attachment plate portion 73), the water can be reliably prevented from accumulating in the interconnecting portion of the attachment plate portion 73 and the lower frame portion 75 and in the vicinity of that interconnecting portion because the slits 75a to 75c that serve as the water drainage portions are formed in the interconnecting portion of the attachment plate portion 73 that serves as the lengthwise plate portion and the lower frame portion 75 that serves as the sideways plate portion and/or in the vicinity of that interconnecting portion where it is easy for water to accumulate.

### (F)

In the electrical equipment assembly 7 of the present embodiment, when water enters between the control board 91 and the frame 71 (more specifically, the attachment plate portion 73), the water can be reliably prevented from accumulating in the interconnecting portion of the attachment plate portion 73 and the lower frame portion 75 and in the vicinity of that interconnecting portion because the slits 75a to 75c that serve as the water drainage portions are formed in the lower frame portion 75 that is positioned on the lowermost side of the portion between the control board 91 and the frame 71. Further, when the lower frame portion 75 and the control board 91 are disposed in extremely close proximity to each other as in the present embodiment, the water can be reliably prevented from accumulating in the portion between the lower frame portion 75 and the control board 91 and in the vicinity of that portion.

In particular, in the electrical equipment assembly 7 of the present embodiment, the slits 75a to 75c that serve as the water drainage portions are formed so as to cut across the lower side of the control board 91 and extend as far as the end portion of the lower frame portion 75 on the opposite side of the blower chamber S1 side, and water can be drained from the portion between the lower frame portion 75 and the control board 91 where the clearance is the narrowest, so water can be reliably prevented from accumulating in the portion between the lower frame portion 75 and the control board 91 and in the vicinity of that portion.

### (G)

In the electrical equipment assembly 7 of the present embodiment, the water guide ribs 73c to 73k and 73m that serve as projecting portions that project toward the control board from the surface of the attachment plate portion 73 on the control board side (in the present embodiment, the surface on the opposite side of the blower chamber S1 side) and extend downward toward the slits 75a to 75c that serve as the drainage portions are formed on the attachment plate portion 73 that serves as the lengthwise plate portion, and the water guide paths are configured by the water guide ribs 73c to 73k and 73m, so the function of speedily guiding the water that is present between the control board 91 and the frame 71 (more specifically, the attachment plate portion 73) to the slits 75a to 75c is obtained, which can also contribute to improving the strength of the attachment plate portion 73 of the frame 71.

Moreover, in the electrical equipment assembly 7 of the present embodiment, the lower ends of the water guide ribs 73c to 73e, 73i, 73k and 73m are connected to the slits 75a to 75c and integrated with the top surface of the lower frame portion 75, so this also contributes to improving the strength of the lower frame portion 75 in which the slits 75a to 75c are formed.

### (H)

In the electrical equipment assembly 7 of the present embodiment, the inverter control element 92 is attached to the surface, on the control board side, of the attachment plate portion 73 that serves as the lengthwise plate portion and the heat sink 94 is attached to the surface of the attachment plate portion 73 on the opposite side of the control board 91 side (in the present embodiment, the surface on the blower chamber S1 side) for cooling during operation of the inverter control element 92, so there is the potential for water to enter from the portion of the attachment plate portion 73 to which the heat sink 94 is attached (that is, the attachment plate opening 73a and the screw holes 73b), but even when water enters between the control board 91 and the frame 71 (more specifically, the attachment plate portion 73) from the portion to which the heat sink 94 is attached, the water that is present between the control board 91 and the frame 71 can be guided to the slits 75a to 75c, speedily drained, and prevented from accumulating, because the water guide ribs 73c to 73k and 73m that serve as the water guide paths are formed on the lower side of the portion on the attachment plate portion 73 to which the heat sink 94 is attached.

Moreover, in the electrical equipment assembly 7 of the present embodiment, the heat sink 94 is disposed in a position that faces the partition plate opening 28a that is an opening in the partition plate 28, and it becomes easy for water adhere also to the attachment plate portion 73 that serves as the lengthwise plate portion of the frame 71, but because the slits 75a to 75c that serve as the water drainage portions are disposed further on the lower side than the partition plate opening 28a, it becomes difficult for water adhering to the attachment plate portion 73 to enter between the control board 91 and the frame 71 through the slits 75a to 75c.

### (7) Other Embodiments

An embodiment of the present invention has been described above on the basis of the drawings, but the specific configuration thereof is not limited to the embodiment and is alterable in a range that does not depart from the gist of the invention.

### (A)

In the preceding embodiment, the water guide paths are configured by forming, in the surface of the attachment plate portion 73 that serves as the lengthwise plate portion that faces the control board 91, the water guide ribs 73c to 73k and 73m that serve as the water drainage portions, but the invention is not limited to this. For example, grooves may also be disposed in the surface of the attachment plate portion 73 that faces the control board 91. In this case, it is difficult to obtain the effect of improving the strength of the frame 71 in comparison to when the projecting portions are disposed, but the function of guiding water to the slits 75a to 75c that serve as the water drainage portions can be obtained.

### (B)

In the preceding embodiment, the slits 75a to 75c that serve as the water drainage portions are formed just in the lower frame portion 75 that serves as the sideways plate portion, but the slits may also be formed in the attachment plate portion 73 that serves as the lengthwise plate portion. For example, it is conceivable to form the slits 75a to 75c of the preceding embodiment such that they extend upward from the lower end portion of the attachment plate portion 73. It will be noted that, in this case also, it is preferable for the upper ends of the slits 75a to 75c to extend to an extent that they do not reach the lower end of the partition plate opening 28a.

### INDUSTRIAL APPLICABILITY

By utilizing the present invention, it can be made difficult, in an electrical equipment assembly that is disposed inside a casing of an outdoor unit, for problems to occur even when water enters between a control board and a frame, such as the water contacting the pattern on the control board and the control board short-circuiting.

1. An electrical equipment assembly for an outdoor unit of an air conditioner, the electrical equipment assembly comprising:
a control board configured to be disposed lengthwise inside a chamber of the outdoor unit, the control board having electrical parts mounted thereon; and
a frame holding the control board, the frame having with water drainage portions arranged to drain water disposed between the frame and the control board, the water drainage portions being formed in a lower portion of the frame with water guide paths that guide the water to the water drainage portions being formed in a surface of the frame that faces a board surface of the control board.

2. The electrical equipment assembly of claim 1, wherein
the water guide paths are disposed on an upper side of the water drainage portions.

3. The electrical equipment assembly of claim 2, wherein
the frame includes a lengthwise plate portion that faces the board surface of the control board and a sideways plate portion that extends sideways from a surface of the lengthwise plate portion on the control board side such that the sideways plate portion is positioned on a lower side of the control board.

4. The electrical equipment assembly of claim 3, wherein
a vertical direction clearance between the sideways plate portion and the control board is equal to or less than 3 mm.

5. The electrical equipment assembly of claim 3, wherein
the water drainage portions are formed in an interconnecting portion of the lengthwise plate portion and the sideways plate portion and/or in a vicinity of the interconnecting portion.

6. The electrical equipment assembly of claim 3, wherein
the water drainage portions are formed in the sideways plate portion.

7. The electrical equipment assembly of claim 3, wherein
the lengthwise plate portion of the frame includes projecting portions that project toward the control board from the surface of the lengthwise plate portion on the control board side and extend downward toward the drainage portions, and
the water guide paths are configured by the projecting portions.

8. The electrical equipment assembly of claim 3, wherein
an inverter control element is attached to the surface of the lengthwise plate portion on the control board side and a heat sink is attached to a surface of the lengthwise plate portion on an opposite side of the control board side to cool during operation of the inverter control element, and
the water guide paths are formed on a lower side of the portion to which the heat sink is attached.

9. The electrical equipment assembly of claim 8, wherein
the chamber is divided into a blower chamber and a machine chamber by a vertical partition plate having an opening to allow communication between the machine chamber and the blower chamber, the control board being disposed lengthwise in the machine chamber such that the heat sink is disposed in a position that faces the opening in the partition plate, and
the water drainage portions are disposed further on a lower side than the opening.

10. The electrical equipment assembly of claim 1, wherein
the water drainage portions are slits.

11. An outdoor unit of an air conditioner including the electrical equipment assembly of claim 1, the outdoor unit further comprising:
a casing; and
a partition plate that extends vertically so as to divide an inside of the casing into a blower chamber and a machine chamber with the electrical equipment assembly disposed in the machine chamber.

12. The electrical equipment assembly of claim 4, wherein
the water drainage portions are formed in an interconnecting portion of the lengthwise plate portion and the sideways plate portion and/or in a vicinity of the interconnecting portion.

13. The electrical equipment assembly of claim 4, wherein
the water drainage portions are formed in the sideways plate portion.

14. The electrical equipment assembly of claim 4, wherein
the lengthwise plate portion of the frame includes projecting portions that project toward the control board from the surface of the lengthwise plate portion on the control board side and extend downward toward the drainage portions, and
the water guide paths are configured by the projecting portions.

15. The electrical equipment assembly of claim 4, wherein
an inverter control element is attached to the surface of the lengthwise plate portion on the control board side and a heat sink is attached to a surface of the lengthwise plate portion on an opposite side of the control board side to cool during operation of the inverter control element, and
the water guide paths are formed on a lower side of the portion to which the heat sink is attached.

16. The electrical equipment assembly of claim 4, wherein
the chamber is divided into a blower chamber and a machine chamber by a vertical partition plate having an opening to allow communication between the machine chamber and the blower chamber, the control board being disposed lengthwise in the machine chamber such that the heat sink is disposed in a position that faces the opening in the partition plate, and
the water drainage portions are disposed further on a lower side than the opening.

17. The electrical equipment assembly of claim 5, wherein
the lengthwise plate portion of the frame includes projecting portions that project toward the control board from the surface of the lengthwise plate portion on the control board side and extend downward toward the drainage portions, and
the water guide paths are configured by the projecting portions.

18. The electrical equipment assembly of claim 17, wherein
an inverter control element is attached to the surface of the lengthwise plate portion on the control board side and a heat sink is attached to a surface of the lengthwise plate portion on an opposite side of the control board side to cool during operation of the inverter control element, and
the water guide paths are formed on a lower side of the portion to which the heat sink is attached.

19. The electrical equipment assembly of claim 18, wherein
the chamber is divided into a blower chamber and a machine chamber by a vertical partition plate having an opening to allow communication between the machine chamber and the blower chamber, the control board being disposed lengthwise in the machine chamber such that the heat sink is disposed in a position that faces the opening in the partition plate, and
the water drainage portions are disposed further on a lower side than the opening.

20. The electrical equipment assembly of claim 19, wherein
the water drainage portions are slits.
